(19) United States
(12) Patent Application Publication
(10) Pub. No.: US 2012/0098031 A1
(43) Pub. Date: Apr. 26, 2012

(54) DUAL-DIRECTIONAL SILICON CONTROLLED RECTIFIER

(75) Inventor: Yun-Chiang WANG, Chupei City (TW)

(73) Assignee: Feature Integration Technology Inc., Chupei City (TW)

(21) Appl. No.: 13/240,819

(22) Filed: Sep. 22, 2011

(30) Foreign Application Priority Data
Oct. 22, 2010 (TW) 099136220

(51) Int. Cl. H01L 29/747

(52) U.S. Cl. 257/168; 257/E29.215

(57) ABSTRACT

A Dual-directional Silicon Controlled Rectifier (DSCR) includes a substrate of a first conductivity type, a buried layer formed on the substrate and of a second conductivity type, a first well and a second well formed on the buried layer and of the first conductivity type, a third well formed between the first well and the second well and of the second conductivity type, and a doped region formed between a first semiconductor region and a third semiconductor region and of the second conductivity type. The doped region includes a part of the third well. The DSCR may regulate a breakdown voltage of a junction thereof. Therefore, when an I/O voltage of an Integrated Circuit (IC) is much higher than a working voltage, a false action may not occur.

### CROSS-REFERENCE TO RELATED APPLICATIONS

This non-provisional application claims priority under 35 U.S.C. §119(a) on Patent Application No(s). 099136220 filed in Taiwan, R.O.C. on Oct. 22, 2010, the entire contents of which are hereby incorporated by reference.

### BACKGROUND

1. Technical Field

The present disclosure relates to a Dual-directional Silicon Controlled Rectifier (DSCR), and more particularly to a DSCR having a doped region.

2. Related Art

The development of semiconductor technologies microminiaturize the dimension of a Metal-oxide-semiconductor Field-effect Transistor (MOSFET). The size is reduced to a grade of submicron meter or even deep submicron meter. However, a thinner gate oxide layer is very likely to be damaged when a higher voltage is applied thereto. In a general environment, the value of an electrostatic voltage may be up to thousands or even tens of thousands of volts. Thus the static electricity in an Integrated Circuit (IC) needs to be discharged before being accumulated to a certain amount during design. Consequently an SCR having low on-resistance, low capacitance, low power consumption, and high power current output capability is an effective element for electrostatic protection.

Generally, a dual-polarity SCR has been widely employed for an I/O protection circuit. An earlier SCR is directly manufactured on a silicon substrate and has a low withstand voltage level, so its application is only limited to a general IC process. A conventional SCR with an annular layout also exists, but due to its large layout area and undesirable startup speed resulting from an excessively large structure, the SCR is not widely used either.

Therefore, in order to improve the startup speed of the SCR, a method of reducing a breakdown voltage of the SCR by improving a metal oxide semiconductor structure therein is proposed to modulate a trigger voltage of the SCR. However, it should be noted that, although this method may quickly start the SCR, a working voltage of the IC is limited at the same time. That is to say, the working voltage of the IC is limited between P+/N wells (or N+/P wells) in the metal oxide semiconductor structure and limited below the breakdown voltage before a punchthrough effect occurs, and a false action usually occurs when an input voltage is higher than the working voltage. For example, in a case that an input voltage under the EIA/TIA-232-E specification is ±15 volts, breakdown or punchthrough may easily occur ahead of time, so the SCR cannot be applied to such circuit.

Therefore, it is desirous to develop an SCR with good electrostatic protection efficacy and capable of withstanding a high working voltage.

### SUMMARY

The present disclosure is related a DSCR.

The present disclosure provides a DSCR, which comprises: a substrate, a buried layer, a first well, a second well, a third well, a first semiconductor region, a second semiconductor region, a third semiconductor region, a fourth semiconductor region, and a doped region. The substrate is of a first conductivity type. The buried layer is formed on the substrate, and is of a second conductivity type. The first well and the second well are formed on the buried layer, and are both of the first conductivity type. The third well is formed on the buried layer and between the first well and the second well, and is of the second conductivity type. The first semiconductor region and the second semiconductor region are both formed in the first well. The third semiconductor region and the fourth semiconductor region are both formed in the second well. The doped region is formed between the first semiconductor region and the third semiconductor region, comprises a part of the third well, and is of the second conductivity type.

According to the DSCR of the present disclosure, the doped region further comprises a part of the first well and a part of the second well.

According to the DSCR of the present disclosure, one of the first conductivity type and the second conductivity type is an N-type, and the other is a P-type.

According to the DSCR of the present disclosure, when the first semiconductor region and the third semiconductor region are of the first conductivity type, the second semiconductor region and the fourth semiconductor region are of the second conductivity type.

According to the DSCR of the present disclosure, when the first semiconductor region and the third semiconductor region are of the second conductivity type, the second semiconductor region and the fourth semiconductor region are of the first conductivity type.

Therefore, according to the DSCR of the present disclosure, through the doped region between the first semiconductor region and the third semiconductor region, the carrier concentration is changed or semiconductors of different carrier concentrations in a standard process are used, to regulate the breakdown voltage of a junction thereof, so that the working voltage of an IC is no longer limited below a value that causes the punchthrough effect or below a low breakdown point as in the prior art, thereby greatly increasing the application value and the industrial utilization of the DSCR.

For purposes of summarizing, some aspects, advantages and features of some embodiments of the invention have been described in this summary. Not necessarily all of (or any of) these summarized aspects, advantages or features will be embodied in any particular embodiment of the invention. Some of these summarized aspects, advantages and features and other aspects, advantages and features may become more fully apparent from the following detailed description and the appended claims.

### BRIEF DESCRIPTION OF THE DRAWINGS

The present disclosure will become more fully understood from the detailed description given herein below for illustration only, and thus are not limitative of the present disclosure, and wherein:

FIG. 1A is a schematic structural diagram of a DSCR according to a first embodiment of the present disclosure;

FIG. 1B is a schematic structural diagram of a DSCR according to a second embodiment of the present disclosure;

FIG. 1C is a schematic structural diagram of a DSCR according to a third embodiment of the present disclosure;

FIG. 1D is a schematic structural diagram of a DSCR according to a fourth embodiment of the present disclosure;

FIG. 2A is a schematic diagram of positive working voltage-current of the DSCR in FIG. 1A;

FIG. 2B is a schematic diagram of negative working voltage-current of the DSCR in FIG. 1A;

FIG. 3A is a schematic structural diagram of a DSCR according to a fifth embodiment of the present disclosure;

FIG. 3B is a schematic structural diagram of a DSCR according to a sixth embodiment of the present disclosure;

FIG. 3C is a schematic structural diagram of a DSCR according to a seventh embodiment of the present disclosure; and

FIG. 3D is a schematic structural diagram of a DSCR according to an eighth embodiment of the present disclosure.

### DETAILED DESCRIPTION

The detailed features and advantages of the present disclosure are described below in great detail through the following embodiments, and the content of the detailed description is sufficient for those skilled in the art to understand the technical content of the present disclosure and to implement the present disclosure there accordingly. Based upon the content, the claims, and the drawings of the specification, those skilled in the art can easily understand the relevant objectives and advantages of the present disclosure.

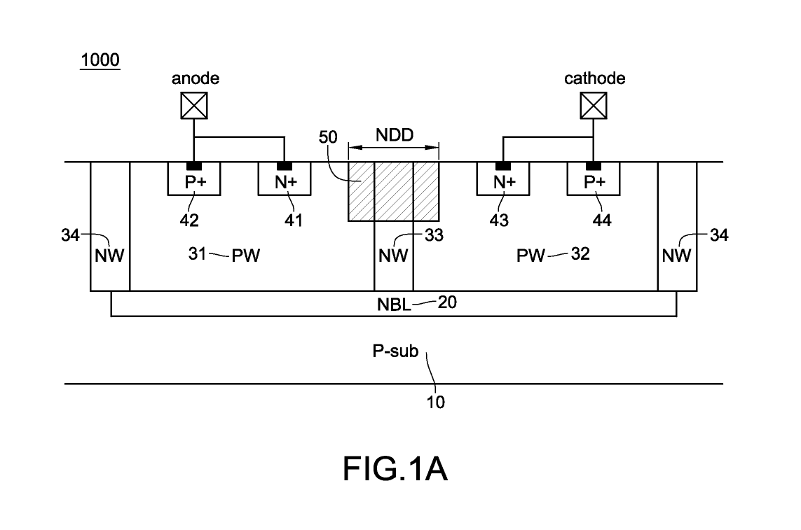

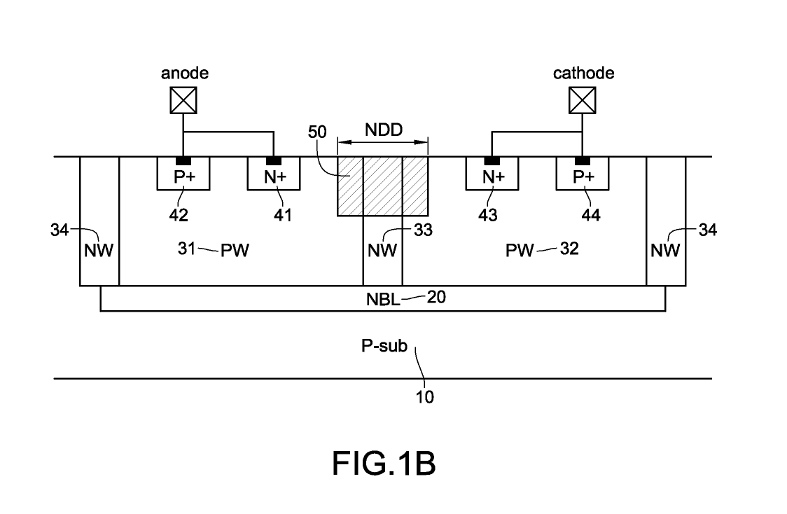

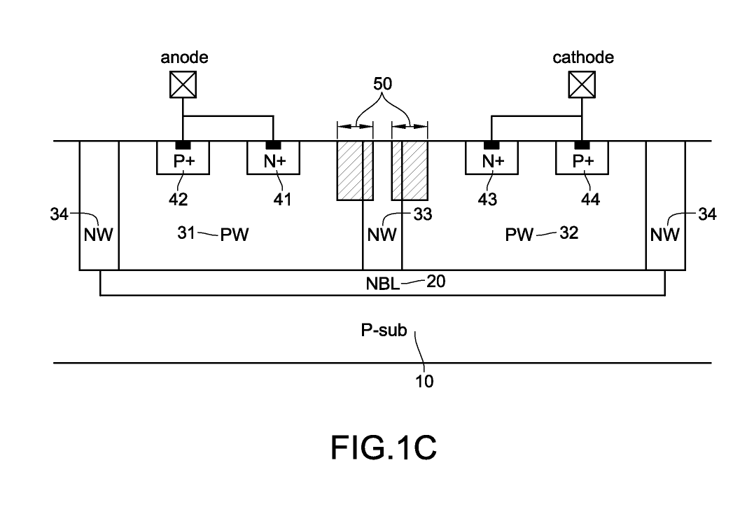

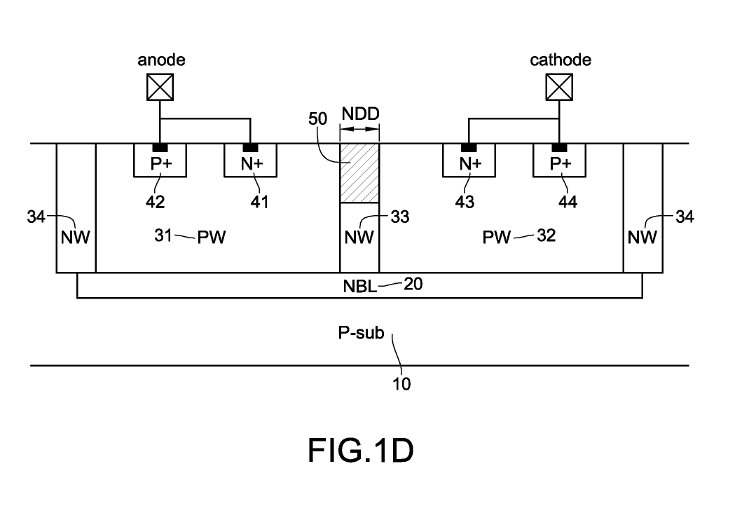

FIG. 1A is a schematic structural diagram of a DSCR according to a first embodiment of the present disclosure. The DSCR 1000 comprises a P-type substrate 10, which has an N-type buried layer (NBL) 20 thereon. The NBL 20 comprises a P-type first well 31, a P-type second well 32, and an N-type third well 33 thereon. The N-type third well 33 is configured between the P-type first well 31 and the P-type second well 32.

According to the embodiment of the present disclosure, an N-type fourth well 34 is further provided between the P-type first well 31, the NBL 20, and the P-type substrate 10. Likewise, the N-type fourth well 34 may also be configured between the P-type second well 32, the NBL 20, and the P-type substrate 10. The N-type fourth well 34 may be, but is not limited to, an undoped epitaxy layer, or is any N-type conductive region, such as an N-type epitaxy layer or an N-type well region.

The P-type first well 31 comprises an N-type first semiconductor region 41 and a P-type second semiconductor region 42 jointly connected to an anode. The P-type second well 32 comprises an N-type third semiconductor region 43 and a P-type fourth semiconductor region 44 jointly connected to a cathode. A manner of connecting the semiconductor regions to the anode and the cathode may be shown in FIG. 1B, where the N-type first semiconductor region 41 and the P-type second semiconductor region 42 are jointly connected to the cathode, while the N-type third semiconductor region 43 and the P-type fourth semiconductor region 44 are jointly connected to the anode.

As shown in FIG. 1A, an N-type doped region 50 is configured between the N-type first semiconductor region 41 and the N-type third semiconductor region 43, and comprises a part of the P-type first well 31, a part of the P-type second well 32, and a part of the N-type third well 33. Therefore, for the N-type doped region 50, an N-type region of a doped concentration is formed between the N-type first semiconductor region 41, the N-type third semiconductor region 43, the P-type first well 31, and the P-type second well 32.

FIG. 1C is a schematic structural diagram of a DSCR according to another embodiment of the present disclosure. The N-type doped region 50 may be designed as a discontinuous implant region. FIG. 1D is a schematic structural diagram of a DSCR according to still another embodiment of the present disclosure. As shown in FIG. 1D, the N-type doped region 50 may also selectively only comprise a part of the N-type third well 33. Each of the foregoing implementation manners may be used to achieve the efficacy of the present disclosure (described in detail below).

According to the embodiment of the present disclosure, the N-type doped region 50 may be used to effectively extend an original breakdown point between the N-type first semiconductor region 41 and the P-type first well 31 to a junction between the P-type first well 31 and the N-type doped region 50, and likewise, effectively extend an original breakdown point between the N-type third semiconductor region 43 and the P-type second well 32 to a junction between the P-type second well 32 and the N-type doped region 50, so that the withstand voltage of the DSCR 1000 is effectively changed (that is, the breakdown voltage thereof is changed). Therefore, when the DSCR according to the first embodiment to the fourth embodiment of the present disclosure is applied in a case that the I/O voltage is higher than the working voltage, the DSCR may still be used as an effective element maintaining the rectification and the electrostatic protection efficacy.

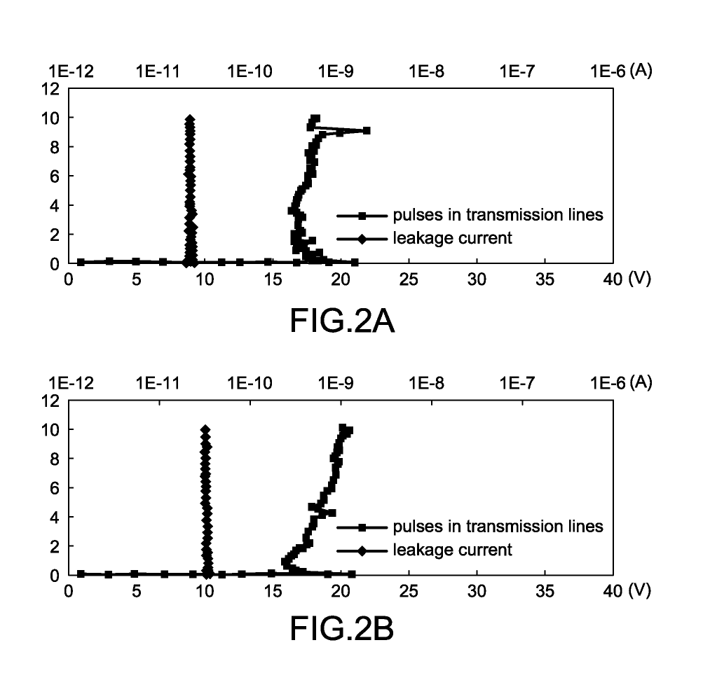

FIG. 2A and FIG. 2B are respectively schematic diagrams of positive working voltage-current and negative working voltage-current of the DSCR in FIG. 1A. It may be seen from FIG. 2A and FIG. 2B that, the breakdown voltage of the DSCR 1000 is already effectively increased to 20 volts, so even if an input voltage under the EIA/TIA-232-E specification is ±15 volts, the DSCR 1000 is still applicable without causing a false action, and maintains low signal loss and high electrostatic protection capability.

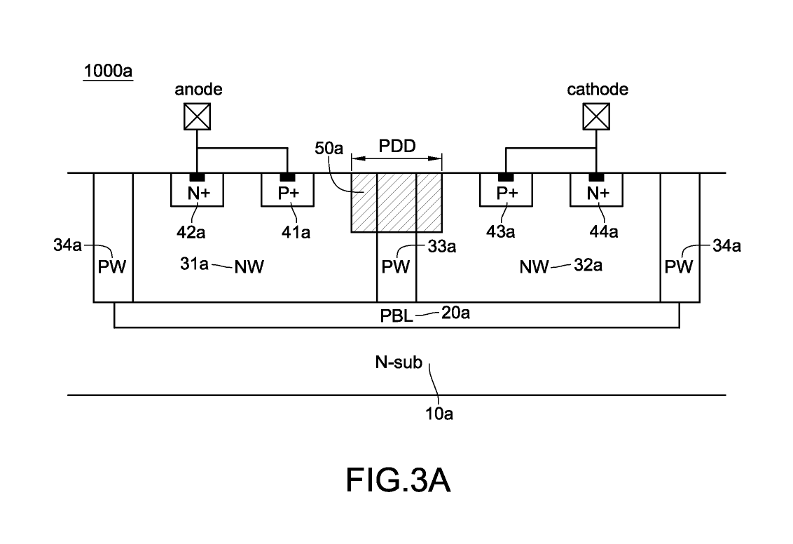

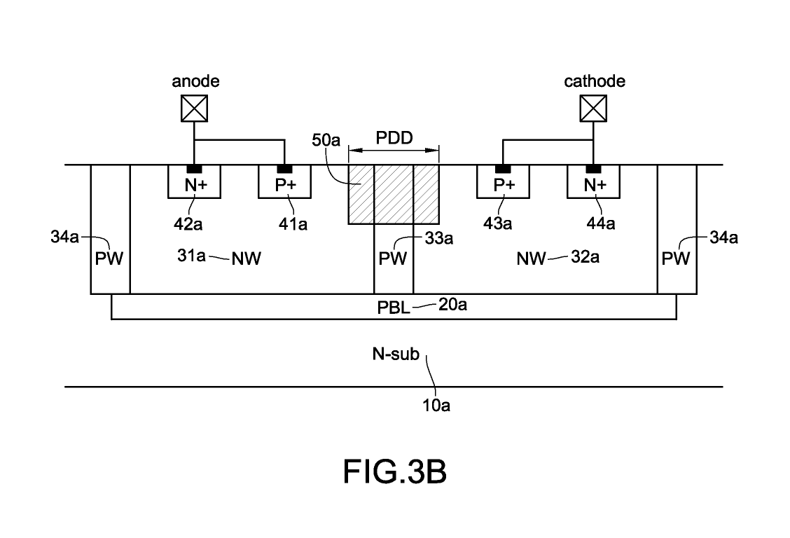

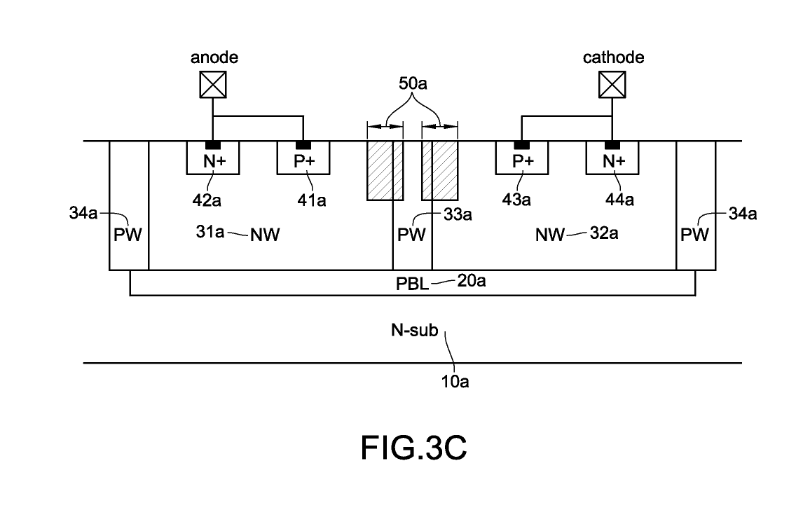

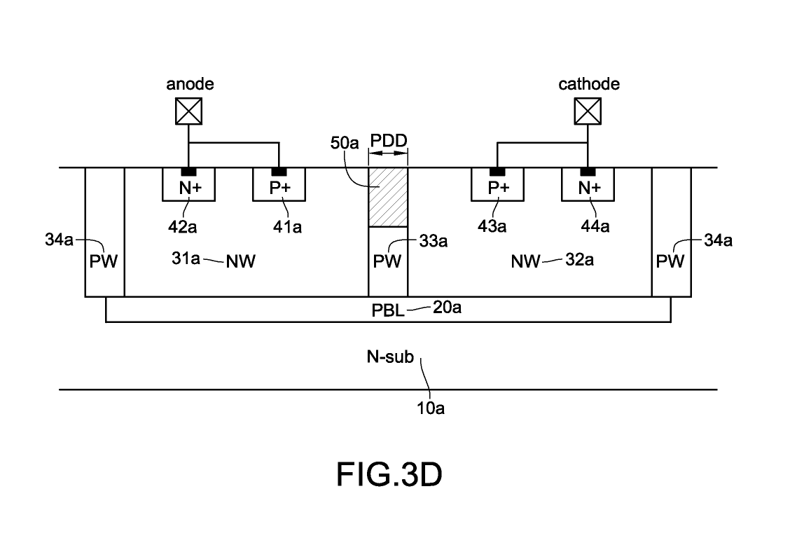

In the first embodiment to the fourth embodiment of the present disclosure (as shown in FIG. 1A to FIG. 1D), the P-type substrate used as an embodiment of the DSCR is illustrated. Conductivity types of the elements (comprising: the buried layer, the first well to the third well, and the doped region) are all determined according to a conductivity type of the P-type substrate. For example, the DSCR may also use the N-type substrate as another embodiment for illustration, and FIG. 3A is a schematic structural diagram of a DSCR according to a fifth embodiment of the present disclosure, which uses an N-type substrate as a base material thereof.

The DSCR 1000a comprises an N-type substrate 10a, a P-type buried layer (PBL) 20a, an N-type first well 31a, an N-type second well 32a, a P-type third well 33a, a P-type fourth well 34a, and a P-type doped region 50a. The N-type first well 31a comprises a P-type first semiconductor region 41a and an N-type second semiconductor region 42a jointly connected to an anode. The N-type second well 32a comprises a P-type third semiconductor region 43a and an N-type fourth semiconductor region 44a jointly connected to a cathode. Conductivity types of the first semiconductor region, the second semiconductor region, the third semiconductor region, and the fourth semiconductor region are not intended to limit the scope of the present disclosure. In the embodiment of the present disclosure, when the first semiconductor region and the third semiconductor region are N-type semiconductor regions corresponding to the P-type substrate, the second semiconductor region and the fourth semiconductor region are of a P-type; while when the first semiconductor region and the third semiconductor region are P-type semiconductor regions corresponding to the N-type substrate, the second semiconductor region and the fourth semiconductor region are of an N-type, which can be designed according to the actual circuit application situation.

Furthermore, the same as the first embodiment of the present disclosure, the manners of connecting the DSCR 1000a to the anode and the cathode may be exchanged, and the P-type doped region 50a may also be selectively set as a discontinuous implant region, or only comprises a part of the P-type third well 33a, which are respectively shown in FIG. 3B, FIG. 3C, and FIG. 3D, and may also be used to achieve the efficacy of the present disclosure.

In view of the above, the DSCR of the present disclosure may effectively prevent the damage caused by the static electricity on the semiconductor element, and maintain the high electrostatic protection capability.

Further, the DSCR having a doped region by controlling the carrier concentration of the doped region or using semiconductors of different carrier concentrations in the standard process may effectively modulate the breakdown voltage of an IC. Therefore, when the I/O voltage is much higher than the working voltage, a false action may not occur, thus effectively solving the problem of the limited trigger voltage of the conventional SCR.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A Dual-directional Silicon Controlled Rectifier (DSCR), comprising:
a substrate of a first conductivity type;
a buried layer, formed on the substrate, and of a second conductivity type;
a first well and a second well, both of the first conductivity type, formed on the buried layer;
a third well, formed on the buried layer and between the first well and the second well, and of the second conductivity type;
a first semiconductor region and a second semiconductor region, formed in the first well;
a third semiconductor region and a fourth semiconductor region, formed in the second well; and
a doped region, formed between the first semiconductor region and the third semiconductor region, wherein the doped region comprises a part of the third well, and is of the second conductivity type.

2. The DSCR according to claim 1, wherein the doped region further comprises a part of the first well and a part of the second well.

3. The DSCR according to claim 1, wherein the first conductivity type is one of an N-type and a P-type, and the second conductivity type is the other of the N-type and the P-type.

4. The DSCR according to claim 1, wherein the first semiconductor region and the second semiconductor region are connected to an anode, and the third semiconductor region and the fourth semiconductor region are connected to a cathode.

5. The DSCR according to claim 1, wherein the first semiconductor region and the second semiconductor region are connected to a cathode, and the third semiconductor region and the fourth semiconductor region are connected to an anode.

6. The DSCR according to claim 1, further comprising at least one fourth well, connected between the first well, the buried layer, and the substrate, and of the second conductivity type.

7. The DSCR according to claim 6, wherein the fourth well is an epitaxy layer.

8. The DSCR according to claim 1, further comprising at least one fourth well, connected between the second well, the buried layer, and the substrate, and of the second conductivity type.

9. The DSCR according to claim 8, wherein the fourth well is an epitaxy layer.

10. The DSCR according to claim 1, wherein the first semiconductor region and the third semiconductor region are one of the first conductivity type and the second conductivity type, and the second semiconductor region and the fourth semiconductor region are the other of the first conductivity type and the second conductivity type.
